(19) United States
(12) Patent Application Publication
(10) Pub. No.: US 2019/0163062 A1
(43) Pub. Date: May 30, 2019

(54) PHOTOSENSITIVE RESIN COMPOSITION AND CURED FILM PREPARED THEREFROM

(71) Applicant: ROHM AND HAAS ELECTRONIC MATERIALS KOREA LTD, Chungcheongnam-do (KR)

(72) Inventors: Jong-Ho NA, Gyeonggi-do (KR); Geun HUH, Gyeonggi-do (KR); Jin KWON, Gyeonggi-do (KR); Jong Han YANG, Gyeonggi-do (KR)

(21) Appl. No.: 16/321,119

(22) PCT Filed: Aug. 10, 2017
(86) PCT No.: PCT/KR2017/008679

§ 371 Date: Jan. 28, 2019

(30) Foreign Application Priority Data
Aug. 19, 2016 (KR) 10-2016-0105487
Aug. 8, 2017 (KR) 10-2017-0100220

(51) Int. Cl. G03F 7/075; G03F 7/022; G03F 7/023

(52) U.S. Cl. CPC G03F 7/0757; G03F 7/0233; G03F 7/0226

(57) ABSTRACT

The present invention relates to a photosensitive resin composition and a cured film prepared therefrom. The photosensitive resin composition additionally includes a thermal acid generator in addition to a conventional siloxane polymer, and an 1,2-quinonediazide compound, and a hydrogen bond between the diazonaphthoquinone group (DNQ) of the quinonediazide compound and the siloxane polymer may be cleaved by an acid generated from the thermal acid generator even if a photobleaching process is not performed during the preparation of a cured film. Accordingly, when the photosensitive resin composition is used a cured film having high transmittance and high resolution may be provided efficiently without any restrictions on a process equipment. In addition, the increase of the transmittance of the cured film may be maximized when acid groups generated from the thermal acid generator is a strong acid having a pKa value of −5 or less.

### TECHNICAL FIELD

The present invention relates to a photosensitive resin composition and a cured film prepared therefrom. In particular, the present invention relates to a positive-type photosensitive resin composition, from which an organic film that has high transmittance and high resolution can be provided even if a photobleaching process is omitted, and a cured film prepared therefrom and used in a liquid crystal display or an organic EL display.

### BACKGROUND ART

Generally, a transparent planarization film is formed on a thin film transistor (TFT) substrate for the purpose of insulation to prevent a contact between a transparent electrode and a data line in a liquid crystal display or an organic EL display. Through a transparent pixel electrode positioned near the data line, the aperture ratio of a panel may be increased and high luminance/resolution may be attained. In order to form such a transparent planarization film, several processing steps are employed to impart a specific pattern profile, and a positive-type photosensitive resin composition is widely employed in this process since fewer processing steps are required. Particularly, a positive-type photosensitive resin composition containing a siloxane polymer is well known as a material having high heat resistance, high transparency, and low dielectric constant.

However, when the conventional positive-type photosensitive resin composition including a siloxane polymer is used to produce a cured film, a photobleaching process is required after exposing and developing processes and prior to a hard bake process. If the hard bake process is performing without the photobleaching process, a hydrogen bond between a quinonediazide compound which is one of the most important component of the positive-type photosensitive resin composition and a siloxane polymer is not removed, and a reddish organic film is obtained instead of a transparent organic film. Thus, transmittance, particularly, transmittance in a wavelength region of about 400 to 600 nm, is deteriorated.

Accordingly, a photobleaching equipment is essentially required in a process equipment to which a positive-type photosensitive resin composition is applied. However, since an equipment for the photobleaching process is not installed in a production process of a negative-type cured film using a photoinitiator instead of a quinonediazide compound as a photosensitive agent, an equipment for a photobleaching process should be additionally installed in case of applying a positive-type photosensitive resin composition to a process equipment for producing a negative-type cured film.

### DISCLOSURE OF INVENTION

### Technical Problem

Accordingly, it is an object of the present invention to provide a positive-type photosensitive resin composition which may provide an organic film having high transmittance and high resolution even if a photobleaching process is omitted, and a cured film prepared therefrom and used in a liquid crystal display or an organic EL display.

### Solution to Problem

In accordance with one aspect of the present invention, there is provided a photosensitive resin composition comprising (A) a siloxane polymer; (B) a 1,2-quinonediazide compound; and (C) a thermal acid generator having a pKa value of −5 to −24.

In accordance with another aspect of the present invention, there is provided a method of preparing a cured film, comprising coating a photosensitive resin composition on a substrate to form a coating layer; exposing and developing the coating layer to form a pattern; and curing the coating layer on which the pattern is formed without performing a photobleaching process for the coating layer.

In accordance with a further aspect of the present invention, there is provided a silicon-containing cured film formed by the above preparation method.

### Advantageous Effects of Invention

Since the photosensitive resin composition of the present invention additionally includes a thermal acid generator in addition to conventional siloxane polymer and quinonediazide compound, a hydrogen bond between the diazonaphthoquinone group (DNQ) of the quinonediazide compound and the siloxane polymer may be cleaved by an acid generated from the thermal acid generator even without performing a photobleaching process during the manufacture of cured film. Accordingly, when the photosensitive resin composition is used, a curd film having high transmittance and high resolution may be provided efficiently without any restrictions on a process equipment. In addition, acid groups generated from the thermal acid generator may even further maximize the increase of the transmittance of the cured film when the thermal acid generator is a strong acid having a pKa value of −5 or less.

### BEST MODE FOR CARRYING OUT THE INVENTION

The photosensitive resin composition according to the present invention comprises (A) a siloxane polymer, (B) a 1,2-quinonediazide compound, and (C) a thermal acid generator, and may optionally further include (D) an epoxy compound, (E) a solvent, (F) a surfactant, and/or (G) an adhesion assisting agent.

Hereinafter, each component of the photosensitive resin composition will be explained in detail.

In the present disclosure, “(meth)acryl” means “acryl” and/or “methacryl”, and “(meth)acrylate” means “acrylate” and/or “methacrylate.”

(A) Siloxane Polymer

The siloxane polymer (polysiloxane) includes a condensate of a silane compound and/or a hydrolysate thereof.

In this case, the silane compound or the hydrolysate thereof may be monofunctional to tetrafunctional silane compounds.

As a result, the siloxane polymer may include a siloxane structural unit selected from the following Q, T, D and M types.
Q type siloxane structural unit: a siloxane structural unit including a silicon atom and adjacent four oxygen atoms, which may be derived from e.g., a tetrafunctional silane compound or a hydrolysate of a silane compound having four hydrolysable groups.
T type siloxane structural unit: a siloxane structural unit including a silicon atom and adjacent three oxygen atoms, which may be derived from e.g., a trifunctional silane compound or a hydrolysate of a silane compound having three hydrolysable groups.
D type siloxane structural unit: a siloxane structural unit including a silicon atom and adjacent two oxygen atoms (i.e., linear siloxane structural unit), which may be derived from, e.g., a difunctional silane compound or a hydrolysate of a silane compound having two hydrolysable groups.
M type siloxane structural unit: a siloxane structural unit including a silicon atom and one adjacent oxygen atom, which may be derived from, e.g., a monofunctional silane compound or a hydrolysate of a silane compound having one hydrolysable group.

For example, the siloxane polymer (A) may include at least one structural unit derived from a silane compound represented by the following formula 2, and the siloxane polymer may be, for example, a condensate of a silane compound represented by the following formula 2 and/or a hydrolysate thereof.

(R₅)ₙSi(OR₆)₄₋ₙ [Formula 2]

wherein,

R₅ is C₁₋₁₂ alkyl, C₂₋₁₀ alkenyl, or C₆₋₁₅ aryl, wherein, in case that a plurality of R₅ is present in the same molecule, each R₅ may be the same or different, and in case that R₅ is alkyl, alkenyl or aryl, hydrogen atoms may be partially or wholly substituted, and R₅ may include a structural unit containing a heteroatom;

R₆ is hydrogen, C₁₋₆ alkyl, C₂₋₆ acyl, or C₆₋₁₅ aryl, wherein, in case that a plurality of R₆ is present in the same molecule, each R₆ may be the same or different, and in case that R₆ is alkyl, acyl or aryl, hydrogen atoms may be partially or wholly substituted; and

n is an integer of 0 to 3.

Examples of R₅ including a structural unit containing a heteroatom may include ether, ester and sulfide.

The silane compound may be a tetrafunctional silane compound where n is 0, a trifunctional silane compound where n is 1, a difunctional silane compound where n is 2, and a monofunctional silane compound where n is 3.

Particular examples of the silane compound may include, e.g., as the tetrafunctional silane compound, tetraacetoxysilane, tetramethoxysilane, tetraethoxysilane, tetrabutoxysilane, tetraphenoxysilane, tetrabenzyloxysilane, and tetrapropoxysilane; as the trifuntional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d³-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, and 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, and dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, and (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

These silane compounds may be used alone or in combination of two or more thereof.

The conditions for preparing the hydrolysate of the silane compound represented by formula 2 or the condensate thereof are not specifically limited. For example, the desired hydrolysate or the condensate may be prepared by diluting the silane compound of formula 2 in a solvent such as ethanol, 2-propanol, acetone, and butyl acetate; adding thereto water necessary for the reaction, and, as a catalyst, an acid (e.g., hydrochloric acid, acetic acid, nitric acid, and the like) or a base (e.g., ammonia, triethylamine, cyclohexylamine, tetramethylammonium hydroxide, and the like); and then stirring the mixture thus obtained to complete the hydrolytic polymerization reaction.

The weight average molecular weight of the condensate (siloxane polymer) obtained by the hydrolytic polymerization of the silane compound of formula 2 is preferably in a range of 500 to 50,000. Within this range, the photosensitive resin composition may have desirable film forming properties, solubility, and dissolution rates in a developer.

The kinds of the solvent and the acid or base catalyst used in the preparation and the amounts thereof may be optionally selected without specific limitation. The hydrolytic polymerization may be carried out at a low temperature of 20° C. or less, but the reaction may also be promoted by heating or refluxing. The time required for the reaction may vary depending on various conditions including the kind and concentration of the silane monomer, reaction temperature, etc. Generally, the reaction time required for obtaining a condensate having a weight average molecular weight of about 500 to 50,000 is in a range of 15 minutes to 30 days; however, the reaction time in the present invention is not limited thereto.

The siloxane polymer (A) may include a linear siloxane structural unit (i.e., D-type siloxane structural unit). The linear siloxane structural unit may be derived from a difunctional silane compound, for example, a silane compound represented by formula 2 where n is 2. Particularly, the siloxane polymer (A) includes the structural unit derived from the silane compound of formula 2 where n is 2 in an amount of 0.5 to 50 mole %, and preferably 1 to 30 mole % based on an Si atomic mole number. Within this range, a cured film may maintain a constant hardness, and exhibit flexible properties, thereby further improving crack resistance with respect to external stress.

Further, the siloxane polymer (A) may include a structural unit derived from a silane compound represented by formula 2 where n is 1 (i.e., T-type structural unit). Preferably, the siloxane polymer (A) includes the structural unit derived from the silane compound represented by formula 2 where n is 1, in an amount ratio of 40 to 85 mole %, more preferably 50 to 80 mole % based on an Si atomic mole number. Within this amount range, the photosensitive resin composition may form a cured film with a more precise pattern profile.

In addition, in consideration of the hardness, sensitivity, and retention rate of a cured film, it is preferable that the siloxane polymer (A) includes a structural unit derived from a silane compound having an aryl group. For example, the siloxane polymer (A) may include a structural unit derived from a silane compound having an aryl group in an amount of 30 to 70 mole %, and preferably 35 to 50 mole % based on an Si atomic mole number. Within this range, the compatibility of a siloxane polymer and an 1,2-naphthoquinonediazide compound is good and thus the excessive decrease in sensitivity may be prevented while attaining more favorable transparency of a cured film. The structural unit derived from the silane compound having an aryl group as R₅ may be a structural unit derived from a silane compound of formula 2 where n is 1 and R₅ is an aryl group, particularly a silane compound of formula 2 where n is 1 and R₅ is phenyl (i.e., T-phenyl type structural unit).

The siloxane polymer (A) may include a structural unit derived from a silane compound represented by formula 2 where n is 0 (i.e., Q-type structural unit). Preferably, the siloxane polymer (A) includes the structural unit derived from the silane compound represented by formula 2 where n is 0, in an amount of 10 to 40 mole %, and preferably 15 to 35 mole % based on an Si atomic mole number. Within this range, the photosensitive resin composition may maintain its solubility in an aqueous alkaline solution at a proper degree during forming a pattern, thereby preventing any defects caused by a reduction in the solubility or a drastic increase in the solubility of the composition.

The term “mole % based on the Si atomic mole number” as used herein refers to the percentage of the number of moles of Si atoms contained in a specific structural unit with respect to the total number of moles of Si atoms contained in all of the structural units constituting the siloxane polymer.

The mole amount of the siloxane unit in the siloxane polymer (A) may be measured from the combination of Si-NMR, ¹H-NMR, ¹³C-NMR, IR, TOF-MS, elementary analysis, determination of ash, and the like. For example, in order to measure the mole amount of a siloxane unit having a phenyl group, an Si-NMR analysis is performed on a total siloxane polymer, a phenyl bound Si peak area and a phenyl unbound Si peak area are then analyzed, and the mole amount can thus be computed from the peak area ratio therebetween.

The photosensitive resin composition of the present invention may include the siloxane polymer (A) in an amount of 50 to 95 wt %, and preferably 65 to 90 wt % based on the total weight of the composition on the basis of the solid content excluding solvents. Within this amount range, the resin composition can maintain its developability at a suitable level, thereby producing a cured film with improved film retention rate and pattern resolution.

(B) 1,2-Quinonediazide Compound

The photosensitive resin composition according to the present invention includes a 1,2-quinonediazide compound (B).

The 1,2-quinonediazide compound may be any compound used as a photosensitive agent in the photoresist field.

Examples of the 1,2-quinonediazide compound include an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound in which a hydroxyl group is substituted with an amino group and 1,2-benzoquinonediazide-4-sulfonic acid or 1,2-benzoquinonediazide-5-sulfonic acid; a sulfonamide of a phenolic compound in which a hydroxyl group is substituted with an amino group and 1,2-naphthoquinonediazide-4-sulfonic acid or 1,2-naphthoquinonediazide-5-sulfonic acid. The above compounds may be used alone or in combination of two or more compounds, and the like.

Examples of the phenolic compound include 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, 2,2,4-trimethyl-7,2′,4′-trihydroxyflavane, and the like.

More particular examples of the 1,2-quinonediazide compound include an ester of 2,3,4-trihydroxybenzophenone and 1,2-naphthoquinonediazide-4-sulfonic acid, an ester of 2,3,4-trihydroxybenzophenone and 1,2-naphthoquinonediazide-5-sulfonic acid, an ester of 4,4′-[1-[4-[1-[4-hydroxyphenyl]-1-methylethyl]phenyl]ethylidene]bisphenol and 1,2-naphthoquinonediazide-4-sulfonic acid, an ester of 4,4′-[1-[4-[1-[4-hydroxyphenyl]-1-methylethyl]phenyl]ethylidene]bisphenol and 1,2-naphthoquinonediazide-5-sulfonic acid, and the like.

The above compounds may be used alone or in combination of two or more compounds.

By using the aforementioned preferable compounds, the transparency of the positive-type photosensitive resin composition may be improved.

The 1,2-quinonediazide compound (B) may be included in the photosensitive resin composition in an amount ranging from 1 to 25 parts by weight, and preferably 3 to 15 parts by weight based on 100 parts by weight of the siloxane polymer (A) on the basis of the solid content excluding solvents. When the 1,2-quinonediazide compound is used in the above amount range, the resin composition may more readily form a pattern, without defects such as a rough surface of a coated film and scum at the bottom portion of the pattern upon development.

(C) Thermal Acid Generator

A thermal acid generator refers to a compound generating an acid at a specific temperature. Such a compound is composed of an acid-generation part and a blocked acid part for blocking acid properties. If the thermal acid generator reaches the specific temperature, the acid-generation part and the blocked acid part are separated to generate an acid.

The thermal acid generator used in the present invention does not generate an acid at a temperature at which pre-bake is performed, but generate an acid at a temperature at which post-bake is performed. The temperature which generates the acid is referred to as an onset temperature, which may be in a range of 130° C. to 220° C.

The thermal acid generator may include amines, quaternary ammoniums, metals, covalent bonds, or the like as the blocked acid part, and, more specifically, may include amines or quaternary ammoniums. Further, the thermal acid generator may include sulfonates, phosphates, carboxylates, antimonates, or the like as the acid part.

A thermal acid generator including amines as the blocked acid part, has advantages that it is well soluble in water and a polar solvent and is applicable even to a solvent-free product. Further, the thermal acid generator including amines can generate an acid over a wide range of temperature, and an amine compound separated after acid generation easily volatilizes to be absent from the applied material. Exemplary thermal acid generators including amines are TAG-2713S, TAG-2713, TAG-2172, TAG-2179, TAG-2168E, CXC-1615, CXC-1616, TAG-2722, CXC-1767, CDX-3012, and the like (available from KING Industries).

A thermal acid generator including quaternary ammoniums as the blocked acid part, in a form of a white solid powder, is soluble in a relatively limited types of solvents. However, due to presence of various kinds of the thermal acid generators including quaternary ammoniums having an onset temperature within a range from 80° C. to 220° C., it is possible to selectively use the thermal acid generators having an onset temperature suitable for a certain process. Further, since in case of the thermal acid generator including quaternary ammoniums, a compound separated after acid generation remains the applied material, it is applicable mainly to a hydrophobic material. Exemplary thermal acid generators including quaternary ammoniums are CXC-1612, CXC-1733, CXC-1738, TAG-2678, CXC-1614, TAG-2681, TAG-2689, TAG-2690, TAG-2700, and the like (available from KING Industries).

The thermal acid generators which include amines or quaternary ammoniums as the blocked acid part, are mostly and preferably used due to variety in their kinds and the above-mentioned advantages.

A thermal acid generator including metals as the blocked acid part generally includes a monovalent or divalent metal ion, functions as a catalyst, and is applicable both to hydrophobic and hydrophilic materials. Exemplary thermal acid generators including metals are CXC-1613, CXC-1739, CXC-1751, and the like (available from KING Industries). The thermal acid generator comprising a certain metal is employed to a limited field in view of an environment and a reliability.

In case of thermal acid generator including covalent bonds as the blocked acid part, a compound separated after acid generation remains the applied material, and thus, it is applicable mainly to a hydrophobic material. Generally, it has a stable structure and, however, it is soluble in a relatively limited types of solvents. Exemplary thermal acid generators including covalent bonds are CXC-1764, CXC-1762, TAG-2507, and the like (available from KING Industries).

The thermal acid generator used in the present invention may have a pKa value of −5 to −24, and particularly, a pKa value of −10 to −24, when the blocked acid part is separated. In this case, pKa means an acid dissociation constant defined by −log Ka, and the pKa value decreases with the increase of acidity.

If an acid generated from the thermal acid generator is stronger, a hydrogen bond between the diazonaphthoquinone group (DNQ) of a quinonediazide compound and a siloxane polymer may be cleaved more easily. For that reason, when a thermal acid generator that generates a strong acid of pKa value of −5 to −24, specifically −10 to −24, is used, a cured film having high transmittance and high resolution may be formed even without performing a photobleaching process.

The thermal acid generator used in the present invention may be a compound represented by the following formula 1:

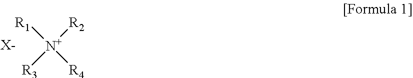

wherein,

R₁ to R₄ are each independently a hydrogen atom, or substituted or unsubstituted C₁₋₁₀ alkyl, C₂₋₁₀ alkenyl, or C₆₋₁₅ aryl, and

X— is one of the compounds represented by the following formulae 3 to 6:

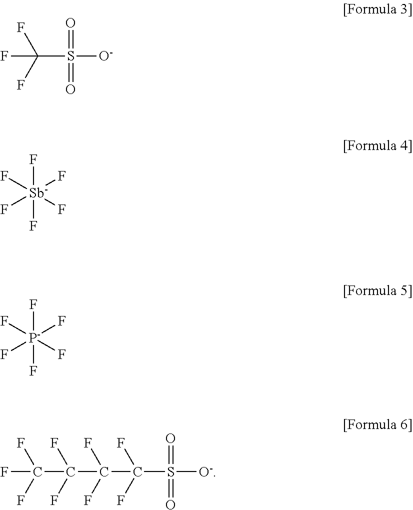

In other words, the thermal acid generator of formula 1 is a compound composed of a blocked acid part

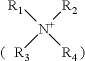

and an acid-generation part (X−).

The thermal acid generator (C) may be included in the photosensitive resin composition based on the solid content excluding a solvent in an amount of 0.1 to 10 parts by weight, and preferably, 0.5 to 5 parts by weight based on 100 parts by weight of the siloxane polymer (A). Within the amount range, pattern formation may be easy, and an organic film having high transmittance of 90% or more, preferably 92% or more, may be more easily obtained by performing a post-bake process without performing a photobleaching process.

(D) Epoxy Compound

In the photosensitive resin composition of the present invention, an epoxy compound is additionally employed together with the siloxane polymer so as to increase the internal density of a siloxane binder, to thereby improve the chemical resistance of a cured film prepared therefrom.

The epoxy compound may be a homo oligomer or a hetero oligomer of an unsaturated monomer including at least one epoxy group.

Examples of the unsaturated monomer including at least one epoxy group may include glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, or a mixture thereof. Preferably, glycidyl methacrylate may be used.

The epoxy compound may be synthesized by any conventional methods well known in the art.

An example of the commercially available epoxy compound may include GHP03 (glycidyl methacrylate homopolymer, Miwon Commercial Co., Ltd.).

The epoxy compound (D) may further include the following structural units.

Particular examples may include any structural unit derived from styrene; a styrene having an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; a styrene having a halogen such as fluorostyrene, chlorostyrene, bromostyrene, and iodostyrene; a styrene having an alkoxy substituent such as methoxy styrene, ethoxystyrene, and propoxystyrene; p-hydroxy-α-methylstyrene, acetylstyrene; an ethylenically unsaturated compound having an aromatic ring such as divinylbenzene, vinylphenol, o-vinylbenzyl methyl ether, m-vinylbenzyl methyl ether, and p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine having an N-vinyl group such as N-vinyl pyrrolidone, N-vinyl carbazole, and N-vinyl morpholine; an unsaturated ether such as vinyl methyl ether, and vinyl ethyl ether; an unsaturated imide such as N-phenylmaleimide, N-(4-chlorophenyl)maleimide, N-(4-hydroxyphenyl)maleimide, and N-cyclohexylmaleimide. The structural unit derived from the above exemplary compounds may be contained in the epoxy compound (D) alone or in combination of two or more thereof.

For polymerizability of the composition, styrene compounds are preferred among these examples.

Particularly, in terms of chemical resistance, it is more preferable that the epoxy compound (D) does not contain a carboxyl group, by not using a structural unit derived from a monomer containing a carboxyl group among these compounds.

The structural unit may be used in an amount ratio of 0 to 70 mole %, and preferably 10 to 60 mole % based on the total number of moles of the structural units constituting the epoxy compound (D). Within this amount range, a cured film may have desirable hardness.

The weight average molecular weight of the epoxy compound (D) may be in a range of 100 to 30,000, and preferably 1,000 to 15,000. If the weight average molecular weight of the epoxy compound is at least 100, a cured film may have improved hardness. Also, if the weight average molecular weight of the epoxy compound is 30,000 or less, a cured film may have a uniform thickness, which is suitable for planarizing any steps thereon. The weight average molecular weight is determined by gel permeation chromatography (GPC, eluent: tetrahydrofuran) using polystyrene standards.

In the photosensitive resin composition of the present invention, the epoxy compound (D) may be included in the photosensitive resin composition in an amount of 0.5 to 50 parts by weight, preferably 1 to 30 parts by weight, and more preferably 5 to 25 parts by weight, 5 to 20 parts by weight based on 100 parts by weight of the siloxane polymer (A) on the basis of the solid content excluding solvents. Within the amount range, the sensitivity of the photosensitive resin composition may be improved.

(E) Solvent

The photosensitive resin composition of the present invention may be prepared as a liquid composition in which the above components are mixed with a solvent. The solvent may be, for example, an organic solvent.

The amount of the solvent in the photosensitive resin composition according to the present invention is not specifically limited. For example, the photosensitive resin composition may contain the solvent in an amount such that its solid content ranges from 10 to 70 wt %, preferably 15 to 60 wt %, and more preferably 20 to 40 wt % based on the total weight of the photosensitive resin composition.

The solid content refers to all of the components included in the resin composition of the present invention excluding solvents. Within the amount range, coatability may be favorable, and an appropriate degree of flowability may be maintained.

The solvent of the present invention is not specifically limited as long as being capable of dissolving each component of the composition and being chemically stable. Examples of the solvent may include alcohol, ether, glycol ether, ethylene glycol alkyl ether acetate, diethylene glycol, propylene glycol monoalkyl ether, propylene glycol alkyl ether acetate, propylene glycol alkyl ether propionate, aromatic hydrocarbon, ketone, ester and the like.

Particular examples of the solvent include methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol methyl ether acetate, propylene glycol ethyl ether acetate, propylene glycol propyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, N-methylpyrrolidone, and the like.

Preferred among these exemplary solvents are ethylene glycol alkyl ether acetates, diethylene glycols, propylene glycol monoalkyl ethers, propylene glycol alkyl ether acetates, and ketones. Particularly, diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol methyl ether acetate, methyl 2-methoxypropionate, γ-butyrolactone, and 4-hydroxy-4-methyl-2-pentanone are preferred.

The above compounds may be used alone or in combination of two or more thereof.

(F) Surfactant

The photosensitive resin composition of the present invention may further include a surfactant to enhance its coatability.

The kind of the surfactant is not limited, but preferred are fluorine-based surfactants, silicon-based surfactants, non-ionic surfactants and the like.

Specific examples of the surfactants may include fluorine- and silicon-based surfactants such as FZ-2122 manufactured by Dow Corning Toray Silicon Co., Ltd., BM-1000, and BM-1100 manufactured by BM CHEMIE Co., Ltd., Megapack F-142 D, Megapack F-172, Megapack F-173, and Megapack F-183 manufactured by Dai Nippon Ink Chemical Kogyo Co., Ltd., Florad FC-135, Florad FC-170 C, Florad FC-430, and Florad FC-431 manufactured by Sumitomo 3M Ltd., Sufron S-112, Sufron S-113, Sufron S-131, Sufron S-141, Sufron S-145, Sufron S-382, Sufron SC-101, Sufron SC-102, Sufron SC-103, Sufron SC-104, Sufron SC-105, and Sufron SC-106 manufactured by Asahi Glass Co., Ltd., Eftop EF301, Eftop EF303, and Eftop EF352 manufactured by Shinakida Kasei Co., Ltd., SH-28 PA, SH-190, SH-193, SZ-6032, SF-8428, DC-57, and DC-190 manufactured by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like, polyoxyethylene aryl ethers including polyoxyethylene octylphenyl ether, polyoxyethylene nonylphenyl ether, and the like, and polyoxyethylene dialkyl esters including polyoxyethylene dilaurate, polyoxyethylene distearate, and the like; and organosiloxane polymer KP341 (manufactured by Shin-Etsu Chemical Co., Ltd.), (meth)acrylate-based copolymer Polyflow No. 57 and 95 (Kyoei Yuji Chemical Co., Ltd.), and the like. They may be used alone or in combination of two or more thereof.

The surfactant (F) may be contained in the photosensitive resin composition in an amount ratio such that the solid content excluding solvents ranges from 0.001 to 5 parts by weight, and preferably 0.05 to 2 parts by weight based on 100 parts by weight of the siloxane polymer (A). Within the amount range, the coatability of the composition may be improved.

(G) Adhesion Assisting Agent

The photosensitive resin composition of the present invention may additionally include an adhesion assisting agent to improve the adhesiveness with a substrate.

The adhesion assisting agent may include at least one reactive group selected from the group consisting of a carboxyl group, a (meth)acryloyl group, an isocyanate group, an amino group, a mercapto group, a vinyl group and an epoxy group.

The kind of the adhesion assisting agent is not specifically limited, and examples thereof may include at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, and β-(3,4-epoxycyclohexyl)ethyltrimethoxysilane, and preferable examples may include γ-glycidoxypropyltriethoxysilane, γ-glycidoxypropyltrimethoxysilane, or N-phenylaminopropyltrimethoxysilane, which may increase retention rate and have good adhesiveness with a substrate.

The adhesion assisting agent (G) may be contained in an amount such that the solid content excluding solvents ranges from 0.001 to 5 parts by weight, preferably 0.01 to 2 parts by weight based on 100 parts by weight of the siloxane polymer (A). Within the amount range, the deterioration of resolution may be prevented, and the adhesiveness of a coating to a substrate may be further improved.

Besides, other additive components may be included in the photosensitive resin composition of the present invention only if the physical properties thereof are not adversely affected.

The photosensitive resin composition of the present invention may be used as a positive-type photosensitive resin composition.

Particularly, the photosensitive resin composition of the present invention additionally includes a thermal acid generator in addition to the conventional siloxane polymer and quinonediazide compound, and a hydrogen bond between the diazonaphthoquinone group (DNQ) of the quinonediazide compound and the siloxane polymer may be cleaved by an acid generated from the thermal acid generator even without performing a photobleaching process during the manufactured of a cured film. Accordingly, when the photosensitive resin composition is used, a curd film having high transmittance and high resolution may be provided efficiently without any restrictions on a process equipment. In addition, acid groups generated from the thermal acid generator may even further maximize the increase of the transmittance of the cured film when the thermal acid generator is a strong acid and the pKa value thereof is −5 or less.

In addition, the present invention provides a method of preparing a cured film, comprising coating a photosensitive resin composition on a substrate to form a coating layer; exposing and developing the coating layer to form a pattern; and curing the coating layer on which the pattern is formed without performing a photobleaching process for the coating layer.

The coating step may be carried out by a spin coating method, a slit coating method, a roll coating method, a screen printing method, an applicator method, and the like, in a desired thickness of, e.g., 1 to 25 μm.

Then, particularly, the photosensitive resin composition coated on the substrate may be subjected to pre-bake at a temperature of, for example, 60 to 130° C. to remove solvents; then exposed to light using a photomask having a desired pattern; and subjected to development using a developer, for example, a tetramethylammonium hydroxide (TMAH) solution, to form a pattern on the coating layer. The light exposure may be carried out at an exposure rate of 10 to 200 mJ/cm² based on a wavelength of 365 nm in a wavelength band of 200 to 500 nm. As a light source used for the exposure (irradiation), a low pressure mercury lamp, a high pressure mercury lamp, an extra high pressure mercury lamp, a metal halide lamp, an argon gas laser, etc., may be used; and X-ray, electronic ray, etc., may also be used, if desired.

Then, the patterned coating layer is subjected to post-bake without performing a photobleaching process with respect to the patterned coating layer, for instance, a temperature of 150 to 300° C. for 10 minutes to 2 hours to prepare a desired cured film.

For a conventional positive-type cured film, an exposing process is performed for a certain time period, for example, prior to performing a post-bake process by using an equipment such as an aligner, which is capable of emitting light having a wavelength of 200 nm to 450 nm, at an exposure rate of 200 mJ/cm² based on a wavelength of 365 nm, and this process is referred to as photobleaching. For the conventional positive-type cured film, a photobleaching process is mostly required, but for the cured film prepared from the photosensitive resin composition of the present invention, the photobleaching process may be omitted.

The cured film thus prepared has excellent physical properties in terms of the heat resistance, transparency, dielectric constant, solvent resistance, acid resistance, and alkali resistance.

Therefore, the cured film has excellent light transmittance without surface roughness when the composition is subjected to heat treatment or is immersed in, or comes into contact with a solvent, an acid, a base, etc. Thus, the cured film can be used effectively as a planarization film for a TFT substrate of a liquid crystal display or an organic EL display; a partition of an organic EL display; an interlayer dielectric of a semiconductor device; a core or cladding material of an optical waveguide, etc.

Furthermore, the present invention provides a silicon-containing cured film prepared by the above preparation method, and electronic parts including the cured film as a protective film. As described above, the silicon-containing cured film may have a transmittance of 90% or more, or 92% or more.

### MODE FOR THE INVENTION

Hereinafter, the present invention will be described in more detail with reference to the following examples. However, these examples are only provided to illustrate the present invention, and the scope of the present invention is not limited thereto.

In the following examples, the weight average molecular weight is determined by gel permeation chromatography (GPC) using a polystyrene standard.

### Synthetic Example 1: Synthesis of Siloxane Polymer (a)

To a reactor equipped with a reflux condenser, 40 wt % of phenyltrimethoxysilane, 15 wt % of methyltrimethoxysilane, 20 wt % of tetraethoxysilane, and 20 wt % of pure water were added, and then, 5 wt % of propylene glycol monomethyl ether acetate (PGMEA) was added thereto, followed by refluxing and stirring the mixture in the presence of 0.1 wt % of an oxalic acid catalyst for 7 hours, and then cooling. After that, the reaction product was diluted with PGMEA so that the solid content was 40 wt %. A siloxane polymer having a weight average molecular weight of about 5,000 to 8,000 Da was synthesized.

### Synthetic Example 2: Synthesis of Siloxane Polymer (b)

To a reactor equipped with a reflux condenser, 20 wt % of phenyltrimethoxysilane, 30 wt % of methyltrimethoxysilane, 20 wt % of tetraethoxysilane, and 15 wt % of pure water were added, and then, 15 wt % of PGMEA was added thereto, followed by refluxing and stirring the mixture in the presence of 0.1 wt % of an oxalic acid catalyst for 6 hours, and then cooling. After that, the reaction product was diluted with PGMEA so that the solid content was 30 wt %. A siloxane polymer having a weight average molecular weight of about 8,000 to 13,000 Da was synthesized.

### Synthetic Example 3: Synthesis of Siloxane Polymer (c)

To a reactor equipped with a reflux condenser, 20 wt % of phenyltrimethoxysilane, 30 wt % of methyltrimethoxysilane, 20 wt % of tetraethoxysilane, and 15 wt % of pure water were added, and then, 15 wt % of PGMEA was added thereto, followed by refluxing and stirring the mixture in the presence of 0.1 wt % of an oxalic acid catalyst for 5 hours, and then cooling. After that, the reaction product was diluted with PGMEA so that the solid content was 30 wt %. A siloxane polymer having a weight average molecular weight of about 9,000 to 15,000 Da was synthesized.

### Synthetic Example 4: Synthesis of Epoxy Compound

A three-necked flask equipped with a condenser was placed on a stirrer with an automatic temperature controller. 100 parts by weight of a monomer including glycidyl methacrylate (100 mole %), 10 parts by weight of 2,2′-azobis(2-methylbutyronitrile), and 100 parts by weight of PGMEA were put in the flask, and the flask was charged with nitrogen. The flask was heated to 80° C. while stirring the mixture slowly, and the temperature was maintained for 5 hours to obtain an epoxy compound having a weight average molecular weight of about 6,000 to 10,000 Da. Then PGMEA was added thereto to adjust the solid content thereof to 20 wt %.

### Examples and Comparative Examples: Preparation of Photosensitive Resin Compositions

Photosensitive resin compositions of the following examples and comparative examples were prepared using the compounds obtained in the above synthetic examples.

Besides, the following compounds were used in the examples and comparative examples:
1,2-quinonediazide compound
   MIPHOTO TPA-517, Miwon Commercial Co., Ltd.
      MIPHOTO BCF-530D, Miwon Commercial Co., Ltd.
thermal acid generator
   TAG-2678 (pKa of −10 to −24, KING Industries Co., Ltd.)
      CXC-1615 (pKa of −10 to −24, KING Industries Co., Ltd.)
      TAG-2172 (pKa of 0 to −1, KING Industries Co., Ltd.)
solvent
   propylene glycol monomethyl ether acetate (PGMEA), Chemtronics Co., Ltd.
      [symbol] -butyrolactone (GBL), BASF
surfactant
   silicon-based leveling surfactant, FZ-2122, Dow Corning Toray Silicon Co., Ltd.

### Example 1

27.5 parts by weight of a solution of the siloxane polymer (a) of Synthetic Example 1, 36.3 parts by weight of a solution of the siloxane polymer (b) of Synthetic Example 2, and 36.2 parts by weight of a solution of the siloxane polymer (c) of Synthetic Example 3 were mixed, and then, 5.33 parts by weight of MIPHOTO TPA-517 as 1,2-quinonediazide compound, 1.0 part by weight of TAG-2678 as a thermal acid generator, 23.7 parts by weight of the epoxy compound of Synthetic Example 4, and 1.1 parts by weight of a surfactant based on 100 parts by weight of the total siloxane polymers were uniformly mixed. The mixture was dissolved in a mixture of PGMEA and GBL (PGMEA:GBL=85:15 by weight) as a solvent so that the solid content was 22 wt %. The mixture was stirred for 1 hour and 30 minutes and filtered using a membrane filter having 0.2 μm pores to obtain a composition solution having a solid content of 22 wt %.

### Examples 2 to 5 and Comparative Examples 1 to 4

Composition solutions were prepared by the same method described in Example 1 except for changing the kind and/or amount of each component were changed as described in Table 1 below.

### Experimental Example 1: Evaluation of Surface Morphology

Each of the compositions obtained in the examples and comparative examples was coated on a silicon nitride substrate by spin coating and pre-baked on a hot plate kept at 110° C. for 90 seconds to form a dried film having a thickness of 3.3 μm. The dried film was developed with an aqueous solution of 2.38 wt % tetramethylammonium hydroxide through stream nozzles at 23° C. for 60 seconds to obtain an organic film. Then, the organic film thus obtained was observed with the naked eye and a microscope (STM6-ML, Olympus), and the occurrence of haze (stain) and surface morphology were examined. If white turbidity, haze and crack were not found from the surface examination, the surface morphology was evaluated as good.

### Experimental Example 2: Evaluation of Transmittance

Each of the compositions obtained in the examples and comparative examples was coated on a silicon nitride substrate by spin coating and pre-baked on a hot plate kept at 110° C. for 90 seconds to form a dried film having a thickness of 3.3 μm. The dried film was developed with an aqueous solution of 2.38 wt % tetramethylammonium hydroxide through stream nozzles at 23° C. for 60 seconds. The substrate was then heated in a convection oven at 230° C. for 30 minutes to obtain a cured film. The thickness of the cured film was measured using a non-contact type thickness measuring device (SNU Precision). In addition, the transmittance at a wavelength of 400 nm was measured using a UV spectroscopy (Cary 10) for the cured film. If the transmittance value of the cured film was 90% or more, the transmittance was evaluated as good.

### Experimental Example 3: Evaluation of Sensitivity

Each of the compositions obtained in the examples and comparative examples was coated on a silicon nitride substrate via spin coating, and the coated substrate was pre-baked on a hot plate kept at 110° C. for 90 seconds to form a dried film. The dried film was exposed, through a mask having a pattern consisting of square holes in sizes ranging from 2 μm to 25 μm, to light at an exposure rate of 0 to 200 mJ/cm² based on a wavelength of 365 nm for a certain time period using an aligner (model name: MA6), which emits light having a wavelength of 200 nm to 450 nm, and was developed by spraying an aqueous developer of 2.38 wt % tetramethylammonium hydroxide through nozzles at 23° C. The exposed film was then heated in a convection oven at 230° C. for 30 minutes to obtain a cured film having a thickness of 3.0 μm.

For the hole pattern formed through a mask having a size of 20 μm, the amount of exposure energy required for attaining a critical dimension (CD, unit: μm) of 19 μm was obtained. The lower the exposure energy is, the better the sensitivity of a cured film is.

### Experimental Example 4: Evaluation of Resolution

Using the photosensitive resin compositions prepared in the examples and the comparative examples, cured films were obtained by the same method described in Experimental Example 3. In order to measure the resolution of the pattern for the cured films thus obtained, the minimum size of the pattern was observed using a micro optical microscope (STM6-LM manufactured by Olympus), and the resolution was measured. That is, the minimum pattern dimension after curing with optimal exposure dosage was measured, when the CD of the patterned hole pattern with 20 μm, was 19 μm. When the resolution value decreases, smaller patterns may be attained, and resolution may be improved.

Experimental results are summarized in the following Table 2.

TABLE 1

| Based on | | | | | 1,2- | | | | | | | |
|---|---|---|---|---|---|---|---|---|---|---|---|---|
| 100 parts by | | | | | quinonediazide | | Thermal | | | | | |
| weight of | Siloxane polymer | | | | compound | | acid generator | | | | | Surfactant |
| siloxane | (a + b + c = 100) | | | Epoxy | TPA- | BCF- | TAG- | CXC- | TAG- | Solvent | | FZ- |
| polymer | a | b | c | compound | 517 | 530D | 2678 | 1615 | 2172 | PGMEA | GBL | 2122 |
| Example 1 | 27.5 | 36.3 | 36.2 | 23.7 | 5.33 | — | 1.0 | — | — | 85 | 15 | 1.1 |
| Example 2 | 27.5 | 36.3 | 36.2 | 23.7 | 2.95 | — | 1.0 | — | — | 85 | 15 | 1.0 |
| Example 3 | 27.5 | 36.3 | 36.2 | 23.7 | — | 2.95 | 1.0 | — | — | 85 | 15 | 1.0 |
| Example 4 | 27.5 | 36.3 | 36.2 | 23.7 | 3.11 | — | — | 1.0 | — | 85 | 15 | 1.0 |
| Example 5 | 27.5 | 36.3 | 36.2 | 23.7 | 3.1 | — | 0.5 | — | — | 85 | 15 | 1.0 |
| Comparative | 27.5 | 36.3 | 36.2 | 23.7 | 5.27 | — | — | — | — | 85 | 15 | 1.1 |
| Example 1 | | | | | | | | | | | | |
| Comparative | 27.5 | 36.3 | 36.2 | 23.7 | 2.91 | — | — | — | — | 85 | 15 | 1.1 |
| Example 2 | | | | | | | | | | | | |
| Comparative | 27.5 | 36.3 | 36.2 | 23.7 | — | 2.9 | — | — | — | 85 | 15 | 1.1 |
| Example 3 | | | | | | | | | | | | |
| Comparative | 27.5 | 36.3 | 36.2 | 23.7 | 2.93 | — | — | — | 1.0 | 85 | 15 | 1.1 |
| Example 4 | | | | | | | | | | | | |

TABLE 2

| | Surface morphology after | Transmittance (%) | Sensitivity | Resolution |
|---|---|---|---|---|
| | developing process | (based on thickness of 3.0 μm) | (mJ) | (μm) |
| Example 1 | Good | 92.3 | 70 | 6 |
| Example 2 | Good | 96.0 | 49 | 6 |
| Example 3 | Good | 94.2 | 45 | 5 |
| Example 4 | Good | 92.4 | 45 | 6 |
| Example 5 | Good | 95.4 | 49 | 5 |
| Comparative | Good | 86.4 | 56 | 4 |
| Example 1 | | | | |
| Comparative | Haze occurred (white | 80.7 | 49 | Haze |
| Example 2 | turbidity) | | | occurred-Resolution |
| | | | | unverifiable |
| Comparative | Haze occurred (white | 89.1 | 45 | Haze |
| Example 3 | turbidity) | | | occurred-Resolution |
| | | | | unverifiable |
| Comparative | Good | 85.5 | 49 | 6 |
| Example 4 | | | | |

As shown in Table 2, all the cured films formed from the compositions of example embodiments included in the scope the present invention had excellent surface states, transmittance, sensitivity and resolution, even though a photobleaching process was omitted. In contrast, the cured films obtained from the compositions according to the comparative examples which are not included in the scope of the present invention exhibited at least one inferior result.

1. A photosensitive resin composition, comprising:
(A) a siloxane polymer;
(B) a 1,2-quinonediazide compound; and
(C) a thermal acid generator having a pKa value of −5 to −24.

2. The photosensitive resin composition of claim 1, wherein the thermal acid generator is a compound represented by the following formula 1: 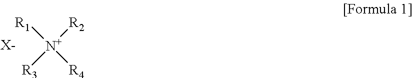
wherein,
R₁ to R₄ are each independently a hydrogen atom, or substituted or unsubstituted C₁₋₁₀ alkyl, C₂₋₁₀ alkenyl, or C₆₋₁₅ aryl, and
X— is one of the compounds represented by the following formulae 3 to 6:

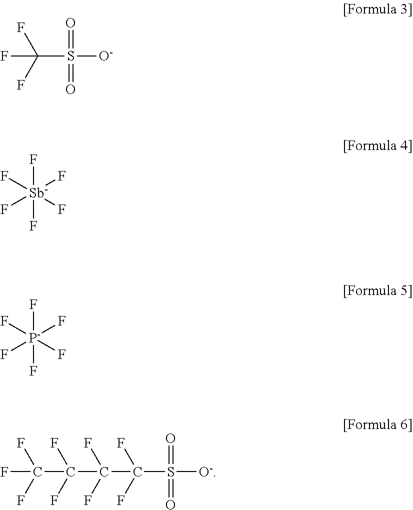

3. The photosensitive resin composition of claim 1, wherein (A) the siloxane polymer comprises at least one structural unit derived from a silane compound represented by the following formula 2:
(R₅)ₙSi(OR₆)₄₋ₙ [Formula 2]
wherein,
R₅ is C₁₋₁₂ alkyl, C₂₋₁₀ alkenyl, or C₆₋₁₅ aryl, wherein, in case that a plurality of R₅ is present in the same molecule, each R₅ may be the same or different, and in case that R₅ is alkyl, alkenyl or aryl, hydrogen atoms may be partially or wholly substituted, and R₅ may comprise a structural unit containing a heteroatom;
R₆ is hydrogen, C₁₋₆ alkyl, C₂₋₆ acyl, or C₆₋₁₅ aryl, wherein, in case that a plurality of R₆ is present in the same molecule, each R₆ may be the same or different, and in case that R₆ is alkyl, acyl or aryl, hydrogen atoms may be partially or wholly substituted; and
n is an integer of 0 to 3.

4. The photosensitive resin composition of claim 1, wherein the photosensitive resin composition further comprises (D) an epoxy compound.

5. The photosensitive resin composition of claim 1, wherein (C) the thermal acid generator is included based on the solid content, in an amount of 0.1 to 10 parts by weight based on 100 parts by weight of the siloxane polymer.

6. A method of preparing a cured film, the method comprising:
coating the photosensitive resin composition of claim 1 on a substrate to form a coating layer;
exposing and developing the coating layer to form a pattern; and
curing the coating layer on which the pattern is formed without performing a photobleaching process for the coating layer.

7. A silicon-containing cured film formed by the method of claim 6.

8. The silicon-containing cured film of claim 7, which has a transmittance of 90% or more.
